(19) United States
(12) Patent Application Publication
(10) Pub. No.: US 2016/0358671 A1
(43) Pub. Date: Dec. 8, 2016

(54) MEMORY CHIP AND STACK TYPE SEMICONDUCTOR APPARATUS INCLUDING THE SAME

(71) Applicant: SK hynix Inc., Icheon-si Gyeonggi-do (KR)

(72) Inventors: Dong Uk LEE, Icheon-si Gyeonggi-do (KR); Kyung Whan KIM, Icheon-si Gyeonggi-do (KR)

(21) Appl. No.: 14/862,446

(22) Filed: Sep. 23, 2015

(30) Foreign Application Priority Data
Jun. 4, 2015 (KR) 10-2015-0078995

(51) Int. Cl. G11C 29/40; G11C 29/44; G11C 29/12

(52) U.S. Cl. CPC G11C 29/40; G11C 29/12015; G11C 29/44

(57) ABSTRACT

A memory chip may include a plurality of channels including a plurality of memory banks and having a separate input/output interface, and each of the plurality of channels may be configured to simultaneously latch compression data groups obtained by compressing respective unit data groups outputted from the plurality of memory banks, sequentially output latched data as test read data according to a read start signal or a read end signal, and generate the read end signal which defines that final data output has ended.

### CROSS-REFERENCES TO RELATED APPLICATION

The present application claims priority under 35 U.S.C. §119(a) to Korean application number 10-2015-0078995, filed on Jun. 4, 2015, in the Korean Intellectual Property Office, which is incorporated herein by reference in its entirety as set forth in full.

### BACKGROUND

### 1. Technical Field

Various embodiments relate to a semiconductor circuit, and more particularly, to a memory chip and a stack type semiconductor apparatus including the same.

### 2. Related Art

A semiconductor apparatus needs a test process for determining whether it normally operates.

Recently, a semiconductor technology uses a scheme in which a plurality of memory chips are stacked on one another and signal transfer is performed through a through via, for example, a through-silicon via (TSV).

Each of the memory chips may include one or more channels.

Each channel of the memory chip may include a plurality of unit memory blocks, for example, a plurality of memory banks.

The channels of the memory chip may have separate input/output interfaces and may independently operate.

As described above, it is necessary to develop a technology for quickly and accurately testing a semiconductor apparatus having one or more channels.

### SUMMARY

An embodiment of the invention may a memory chip that includes a plurality of memory banks configured to simultaneously output previously stored data according to a read command. The memory chip may also include a plurality of data compression blocks configured to generate compression data groups by compressing respective unit data groups outputted from the plurality of memory banks. Further, the memory chip may also include a test control circuit configured to simultaneously latch the compression data groups and sequentially output latched data as test read data according to a read start signal.

An embodiment of the invention may include a memory chip that comprises a plurality of channels including a plurality of memory banks and having a separate input/output interface. Each of the plurality of channels may be configured to simultaneously latch compression data groups obtained by compressing respective unit data groups outputted from the plurality of memory banks; sequentially output latched data as test read data according to a read start signal or a read end signal; and generate the read end signal which defines that final data output has ended.

An embodiment of the invention may include a stack type semiconductor apparatus. The stack type semiconductor apparatus may include a plurality of stacked memory chips in which signal input/output is performed. Each of the plurality of memory chips may include a plurality of channels including a plurality of memory banks; and are be configured to simultaneously latch compression data groups obtained by compressing respective unit data groups outputted from the plurality of memory banks of each of the plurality of channels; sequentially output latched data as test read data according to a read start signal or a read end signal of a previous channel; and generate the read end signal which defines that final data output has ended.

### BRIEF DESCRIPTION OF THE DRAWINGS

FIG. 1 is a sectional view of a stack type semiconductor apparatus 10 according to an embodiment;

FIG. 2 is a layout diagram of a memory chip 100-1 of FIG. 1;

FIG. 3 is a diagram illustrating an internal configuration of a memory chip 100-1 of FIG. 1;

FIG. 4 is a diagram illustrating an internal configuration of a test control circuit of FIG. 3;

FIG. 5 is a diagram illustrating an internal configuration of a control block 400 of FIG. 4;

FIG. 6 is a timing diagram for explaining of an operation of a control block 400 of FIG. 5;

FIG. 7 to FIG. 9 are timing diagrams for explaining of a test method of a memory chip 100-1 according to an embodiment; and

FIG. 10 illustrates an embodiment in which the stack type semiconductor apparatus 10 is incorporated into a system.

### DETAILED DESCRIPTION

Hereinafter, a memory chip and a stack type semiconductor apparatus including the same according to the invention will be described in detail with reference to the accompanying figures through an embodiment. A memory chip capable of improving test time and efficiency and a stack type semiconductor apparatus including the same are described herein. In an embodiment of the invention, a channel having a highest order of the plurality of channels may be configured to perform a data output operation according to the read start signal. In an embodiment of the invention, remaining channels, except for a channel having a highest order of the plurality of channels, may be configured to perform a data output operation according to the read end signal of the previous channel. In an embodiment of the invention, the plurality of channels may be configured to simultaneously output data stored in the plurality of respective memory banks, according to a read command. In an embodiment of the invention, the previous channel may include any one of a plurality of channels in a substantially same chip or any one of a plurality of channels of another memory chip. In an embodiment of the invention, a channel having a highest order of a plurality of channels of a highest or lowest memory chip of the plurality of memory chips may be configured to perform a data output operation according to the read start signal. In an embodiment of the invention, remaining channels, except for a channel having a highest order of a plurality of channels of a highest or lowest memory chip of the plurality of memory chips, may be configured to perform a data output operation according to the read end signal of the previous channel. In an embodiment of the invention, the test read data may be configured to be outputted through the through vias. In an embodiment of the invention, the read end signal may be configured to be transmitted from any one of the plurality of memory chips to another memory chip through the through vias.

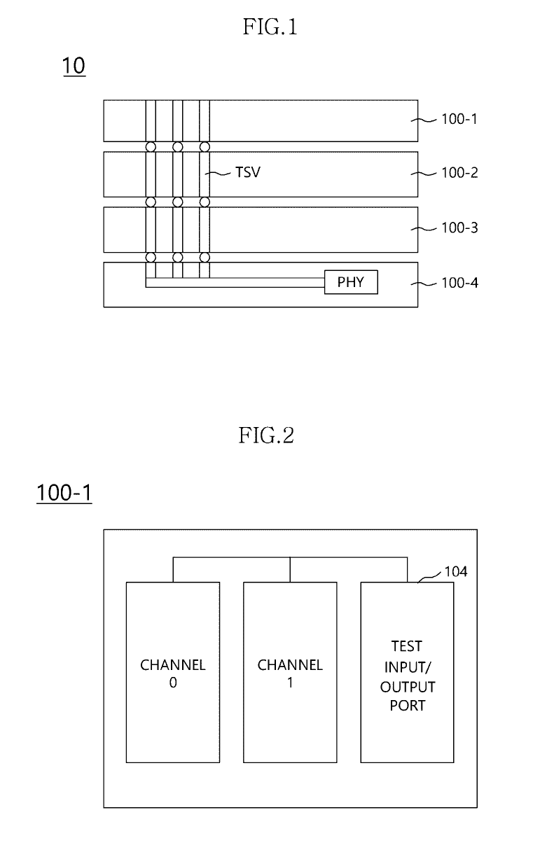

Referring to FIG. 1, a semiconductor apparatus 10 according to an embodiment may include a plurality of stacked memory chips 100-1 to 100-4.

The plurality of stacked memory chips 100-1 to 100-4 may perform signal transfer through a through via, for example, a through-silicon via (TSV).

Among the plurality of stacked memory chips 100-1 to 100-4, the lowermost memory chip 100-4 may include a physical layer PHY as a base chip that performs an interface with an external system.

The other memory chips 100-1 to 100-3, except for the lowermost memory chip 100-4, are core chips and may be configured to be substantially equal to one another.

Each of the memory chips 100-1 to 100-3 may be a core chip including one or more channels.

The respective channels of the memory chips 100-1 to 100-3 may have separate input/output interfaces and may independently operate.

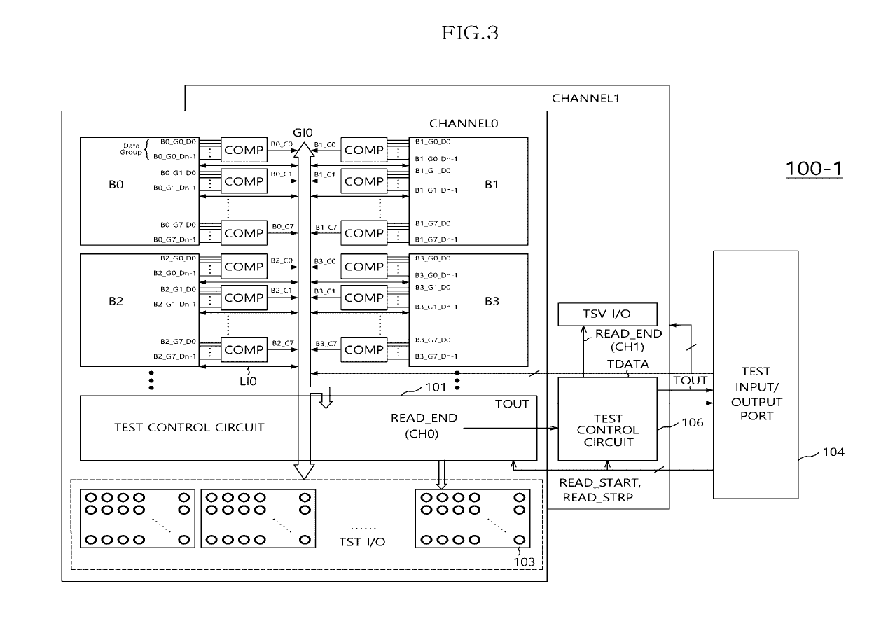

Each channel may include a plurality of unit memory blocks, for example, a plurality of memory banks (which will be described later with reference to FIG. 3).

For example, when the memory chips 100-1 to 100-3 each have two channels, the semiconductor 10 may have the total six channels.

For the purpose of convenience, the six channels included in the memory chips 100-1 to 100-3 may be called a first channel CHANNEL 0 to a sixth channel CHANNEL 5.

Each of the memory chips 100-1 to 100-3 may be configured such that a simultaneous test (for example, a data compression test) is possible without a process of separately selecting a plurality of channels before stack.

Furthermore, the memory chips 100-1 to 100-3 may be configured such that a simultaneous test (for example, a data compression test) is possible without a process of separately selecting all channels of the memory chips 100-1 to 100-3 after stack, which will be described with reference to subsequent figures.

Referring to FIG. 2, the memory chip 100-1 may include a plurality of channels, for example, the first channel CHANNEL 0, the second channel CHANNEL 1, and a test input/output port 104.

The test input/output port 104 may be configured such that a test-related command outside the memory chip 100-1 and test-related data input/output are possible.

Referring to FIG. 3, the first channel CHANNEL 0 of the memory chip 100-1 may include a plurality of memory banks, for example, first to fourth memory banks B0 to B3, a plurality of data compression blocks COMP, a test control circuit 101, a through-via input/output blocks TSV I/O.

The second channel CHANNEL 1 may be configured to be substantially equal to the first channel CHANNEL 0.

The first to fourth memory banks B0 to B3 may be electrically coupled to global input/output lines GIO through local input/output lines LIO.

A test write command and test data TDATA may be inputted through the test input/output port 104.

The first channel CHANNEL 0 and the second channel CHANNEL 1 may simultaneously write the test data TDATA in the first to fourth memory banks B0 to B3 according to the test write command.

The first channel CHANNEL 0 and the second channel CHANNEL 1 may simultaneously output data, which has been written in the first to fourth memory banks B0 to B3, according to a read start signal READ_START.

The global input/output lines GIO may be electrically coupled to the through-via input/output block TSV I/O and the test control circuit 101.

The plurality of data compression blocks COMP may transmit compression data groups B0_C<0:7> to B3_C<0:7>, which are obtained by compressing unit data groups B0_G0_D<0:n−1> to B0_G7_D<0:n−1>, B1_G0_D<0:n−1> to B1_G7_D<0:n−1>, B2_G0_D<0:n−1> to B2_G7_D<0:n−1>, and B3_G0_D<0:n−1> to B3_G7_D<0:n−1> outputted from the first to fourth memory banks B0 to B3, to some of the global input/output lines GIO.

The test control circuit 101 may be configured to simultaneously latch the compression data groups B0_C<0:7> to B3_C<0:7>, sequentially output the latched data as test read data TOUT according to the read start signal READ_START, and provide a read end signal READ_END for defining that the output of the test read data TOUT has been ended to a next channel, that is, the second channel CHANNEL 1.

The through-via input/output block TSV I/O may be divided into a plurality of unit arrays. Further, the test read data TOUT may be outputted through one unit array 103 of the plurality of unit arrays.

When the memory chip 100-1 includes one channel, that is, the first channel, the test control circuit 101 may provide the read end signal READ_END to a channel (for example, a second channel) of another memory chip 100-2 (see FIG. 1) through the through-via input/output block TSV I/O.

The second channel CHANNEL 1 may be configured to be substantially equal to the first channel CHANNEL 0.

A test control circuit 106 of the second channel CHANNEL 1 may provide the read end signal READ_END to a channel (for example, a third channel) of another memory chip 100-2 (see FIG. 1) through the through-via input/output block TSV I/O.

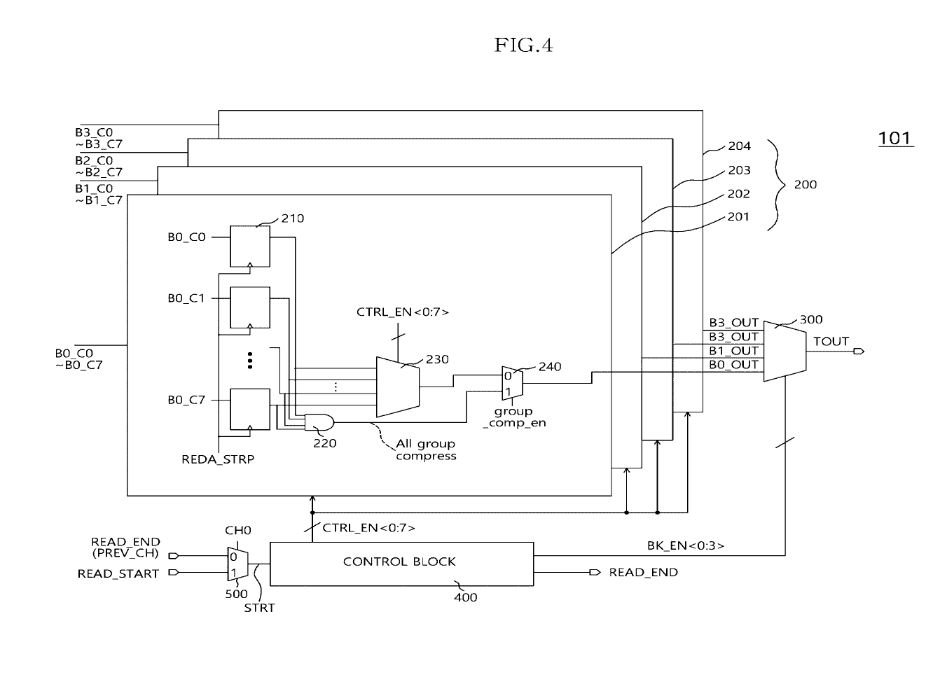

Referring to FIG. 4, the test control circuit 101 may include a data processing block 200, a control block 400, a first multiplexing block 300, and a second multiplexing block 500.

The data processing block 200 may be configured to simultaneously latch the compression data groups B0_C<0:7> to B3_C<0:7> according to a strobe signal READ_STRP; and sequentially output the latched compression data groups B0_C<0:7> is to B3_C<0:7> according to a plurality of output control signals CTRL_EN<0:7>.

The strobe signal READ_STRP may be generated after the data compression by the plurality of data compression blocks COMP of FIG. 3 is performed, before the read end signal READ_END which will be described later.

The data processing block 200 may include data processing units corresponding to the number of memory banks. Since the embodiment includes the first to fourth memory banks B0 to B3, the data processing block 200 may include first to fourth data processing units 201 to 204.

The first to fourth data processing units 201 to 204 may be configured to be substantially equal to one another.

The first data processing unit 201 may include a plurality of latches 210, a logic gate 220, a first multiplexer 230, and a second multiplexer 240.

The plurality of latches 210 may simultaneously latch the compression data groups B0_C<0:7> corresponding to the first memory bank B0 according to the strobe signal READ_STRP.

The logic gate 220 may perform AND on signals latched in the plurality of latches 210 and output a group compression signal All group compress.

The first multiplexer 230 may sequentially select and output the signals latched in the plurality of latches 210 according to a plurality of output control signals CTRL_EN<0:7>.

The second multiplexer 240 may select and output the output of the first multiplexer 230 or the group compression signal All group compress outputted from the logic gate 220 according to a group compression enable signal Group_comp_en.

The first multiplexing block 300 may sequentially select output signals B0_OUT to B3_OUT of the first to fourth data processing units 201 to 204 according to a plurality of bank selection signals BK_EN<0:3>. The first multiplexing block 300 may output the selected signal as the test read data TOUT.

The second multiplexing block 500 may select the read start signal READ_START or the read end signal READ_END, which has been generated in a previous channel, according to channel information CH0, and generate an output signal STRT.

The channel information CH0 may be set to logic high in the first channel CHANNEL 0 and to logic low in the second channel CHANNEL 1.

The invention is an example of the semiconductor chip 100-1 including two channels, and for example, when the semiconductor chip 100-1 includes four channels, the channel information CH0 may be set to logic high in the first channel CHANNEL 0 and to logic low in the other channels CHANNEL 1 to CHANNEL 3.

Since the first channel CHANNEL 0 is logic high, the channel information CH0 may select the read start signal READ_START and generate the output signal STRT.

The control block 400 may generate the plurality of output is control signals CTRL_EN<0:7> and the plurality of bank selection signals BK_EN<0:3> according to an output signal STRT of the second multiplexing block 500, that is, the read start signal READ_START.

The control block 400 may generate the read end signal READ_END, which defines that final data output of a channel including the control block 400, that is, the first channel CHANNEL 0 has been ended, according to the plurality of output control signals CTRL_EN<0:7> and the plurality of bank selection signals BK_EN <0:3>.

Although not illustrated in the figure, in the second channel CHANNEL 1, the channel information CH0 is logic low.

Since the channel information CH0 is logic low, the second multiplexing block 500 of the second channel CHANNEL 1 may select the read end signal READ_END generated in the first channel CHANNEL 0 and generate the output signal STRT.

The control block 400 of the second channel CHANNEL 1 may generate the plurality of output control signals CTRL_EN<0:7> and the plurality of bank selection signals BK_EN<0:3> according to the output signal STRT of the second multiplexing block 500, that is, the read end signal READ_END generated in the first channel CHANNEL 0.

The control block 400 of the second channel CHANNEL 1 may generate the read end signal READ_END which defines that final data output has been ended.

As described above, the read end signal READ_END generated in a previous channel may be transferred to a next channel.

Channels, except for an initial channel, may perform a data output operation according to the read end signal READ_END of the previous channel, generate the read end signal READ_END which defines that its own data output has been ended, and transfer the read end signal READ_END to a next channel.

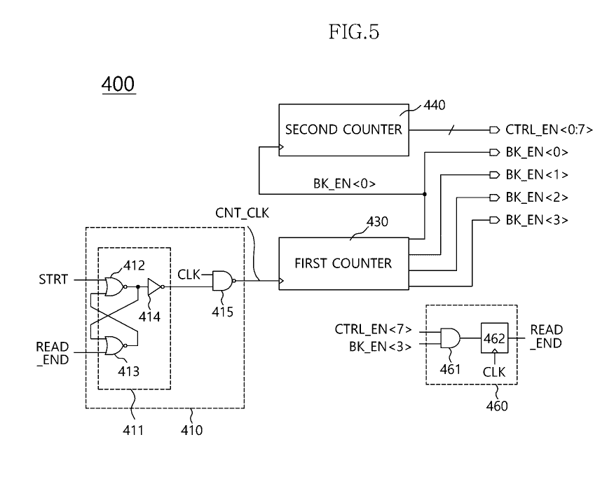

Referring to FIG. 5, the control block 400 may include a count clock generation unit 410, a first counter 430, a second counter 440, and a read end signal generation unit 460.

The count clock generation unit 410 may generate a count clock signal CNT_CLK according to the output signal STRT of the second multiplexing block 500, the read end signal READ_END of the previous channel, and a clock signal CLK.

The count clock generation unit 410 may output clock pulses of the clock signal CLK, which correspond to a period in which the read end signal READ_END of the previous channel has been activated from the time point at which the output signal STRT of the second multiplexing block 500 has been activated, as the count clock signal CNT_CLK. The previous channel may include any one of a plurality of channels in a substantially same chip or any one of a plurality of channels of another memory chip.

The count clock generation unit 410 may include a latch 411 and a logic gate 415.

The latch 411 may include logic gates 412 to 414.

The first counter 430 may generate the plurality of bank selection signals BK_EN<0:3> according to the count clock signal CNT_CLK.

The second counter 440 may generate the plurality of output control signals CTRL_EN<0:7> according to the first signal BK_EN<0> of the plurality of bank selection signals BK_EN<0:3>.

The read end signal generation unit 460 may generate the read end signal READ_END according to the output control signal CTRL_EN<7> and the bank selection signal BK_EN<3> for selecting final output data; that is, the output signal B3_OUT of the fourth data processing unit 204 among the plurality of output control signals CTRL_EN<0:7> and the plurality of bank selection signals BK_EN<0:3>.

The read end signal generation unit 460 may include a logic gate 461 and a flip-flop 462.

The logic gate 461 may perform AND on the output control signal CTRL_EN<7> and the bank selection signal BK_EN<3> and output a resultant.

The flip-flop 462 may latch an output signal of the logic gate 461 according to the clock signal CLK and output the latched signal as the read end signal READ_END.

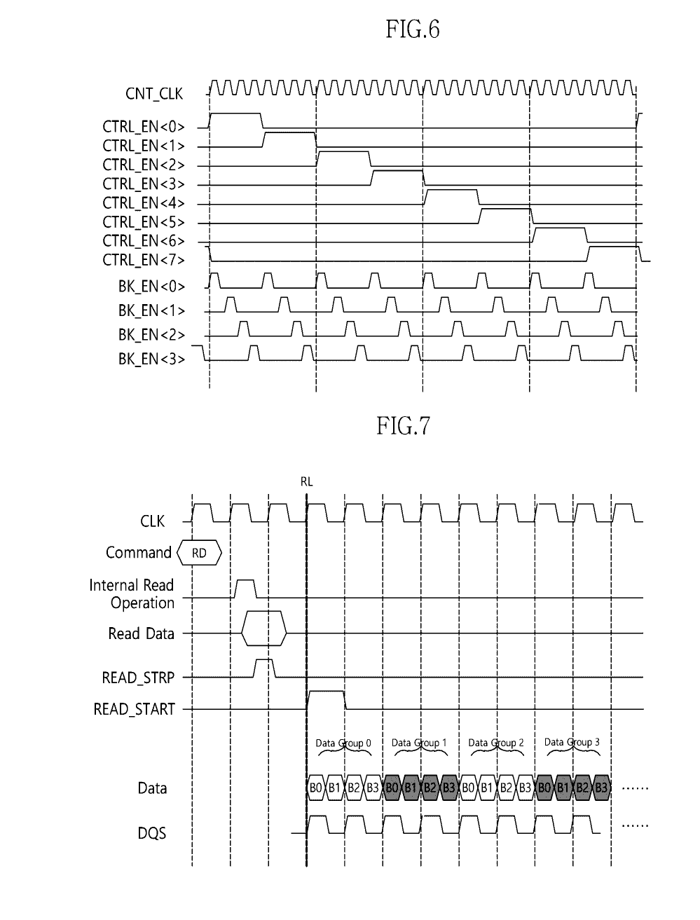

Referring to FIG. 6, during respective activation periods of the plurality of output control signals CTRL_EN<0:7>, the plurality of bank selection signals BK_EN<0:3> may be repeatedly generated.

Accordingly, the data processing block 200 of FIG. 4 may sequentially output the already latched compression data groups B0_C<0:7> to B3_C<0:7> during the activation period of the output control signal CTRL_EN<0> according to a repeated order (B0, B1, B2, B3, B0, . . . , B0, B1, B2, and B3) of the first to fourth memory banks B0 to B3.

In this instance, data corresponding to the respective activation periods of the plurality of output control signals CTRL_EN<0:7> may be called first to eighth data groups Data Group 0 to Data Group 7.

In more detail, the data processing block 200 may sequentially output 1-bit data B0_C<0> corresponding to the first memory bank B0 according to the bank selection signal BK_EN<0>, 1-bit data B1_C<0> corresponding to the second memory bank B1 according to the bank selection signal BK_EN<1>; 1-bit data B2_C<0> corresponding to the third memory bank B2 according to the bank selection signal BK_EN<2>; and 1-bit data B3_C<0> corresponding to the fourth memory bank B3 according to the bank selection signal BK_EN<3> as the first data group Data Group 0 during the activation period of the output control signal CTRL_EN<0>.

Subsequently, the data processing block 200 may sequentially output 1-bit data B0_C<1> corresponding to the first memory bank B0 according to the bank selection signal BK_EN<0>; 1-bit data B1_C<1> corresponding to the second memory bank B1 according to the bank selection signal BK_EN<1>; 1-bit data B2_C<1> corresponding to the third memory bank B2 according to the bank selection signal BK_EN<2>; and 1-bit data B3_C<1> corresponding to the fourth memory bank B3 according to the bank selection signal BK_EN<3> as the second data group Data Group 1 during the activation period of the output control signal CTRL_EN<1>.

In the aforementioned manner, the data processing block 200 may sequentially output the third to eighth data groups Data group 2 B0_C<2>, B1_C<2>, B2_C<2>, and B3_C<2> to Data group 7 B0_C<7>, B1_C<72>, B2_C<7>, and B3_C<7> during the activation periods of the output control signals CTRL_EN<2:7> according to the plurality of bank selection signals BK_EN<0:3>.

Referring to FIGS. 7 to 9, a test method of the memory chip 100-1 according to an embodiment will be described in FIGS. 7 to 9.

In FIG. 7, a test operation when the memory chip 100-1 includes only one channel will be described.

As a read command RD is inputted, data written in a previous test write process may be simultaneously outputted and compressed in the first to fourth memory banks B0 to B3 by an internal read operation, so that read data Read Data, that is, the compression data groups B0_C<0:7> to B3_C<0:7> may be generated.

The compression data groups B0_C<0:7> to B3_C<0:7> may be simultaneously latched in the data processing block 200 of FIG. 4 according to a strobe signal READ_STRP.

The latched compression data groups B0_C<0:7> to B3_C<0:7> may be sequentially outputted as the first to eighth data groups Data Group 0 to Data Group 7 according to an order of the first to fourth memory banks B0 to B3 in response to the read start signal READ_START generated in accordance with a read latency RL.

The sequential output of the first to eighth data groups Data Group 0 to Data Group 7 may be performed based on a data strobe signal DQS.

In FIG. 8, a test method of the memory chip 100-1 according to the all group compress mode will be described.

As the read command RD is inputted, data written in a previous test write process may be simultaneously outputted and compressed in the first to fourth memory banks B0 to B3 by an internal read operation, so that read data Read Data, that is, the compression data groups B0_C<0:7> to B3_C<0:7> may be generated.

The compression data groups B0_C<0:7> to B3_C<0:7> may be simultaneously latched in the data processing block 200 of FIG. 4 according to the strobe signal READ_STRP.

As the group compression enable signal Group_comp_en is activated, the data processing block 200 may sequentially output data, which is obtained by compressing again the compression data groups B0_C<0:7> to B3_C<0:7> respectively corresponding to the first to fourth memory banks B0 to B3, according to an order of the first to fourth memory banks B0 to B3 in response to the read start signal READ_START generated in accordance with a read latency RL.

The output of the data obtained by compressing the compression data groups B0_C<0:7> to B3_C<0:7> again may be performed based on the data strobe signal DQS.

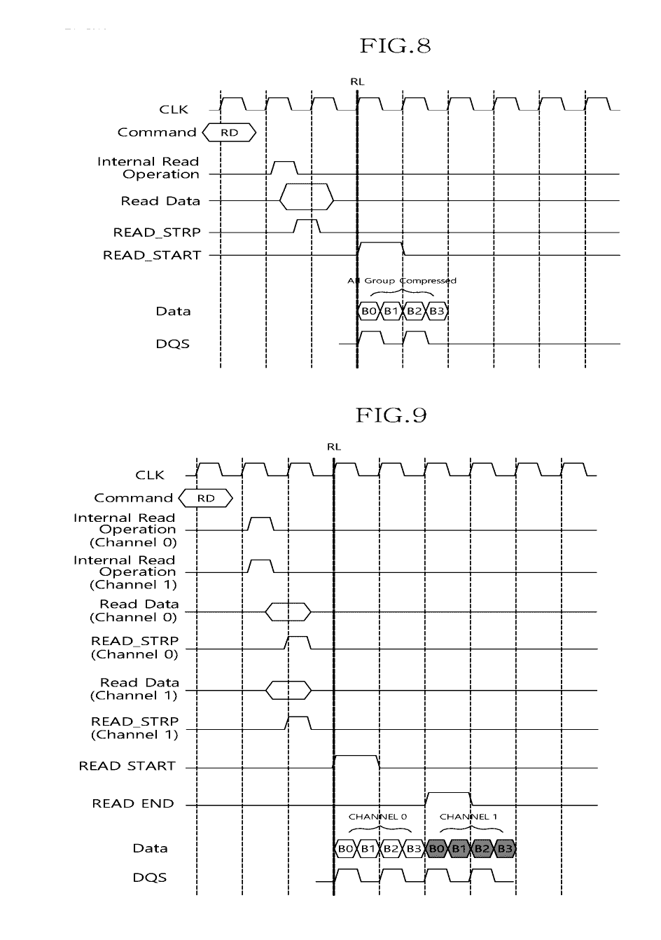

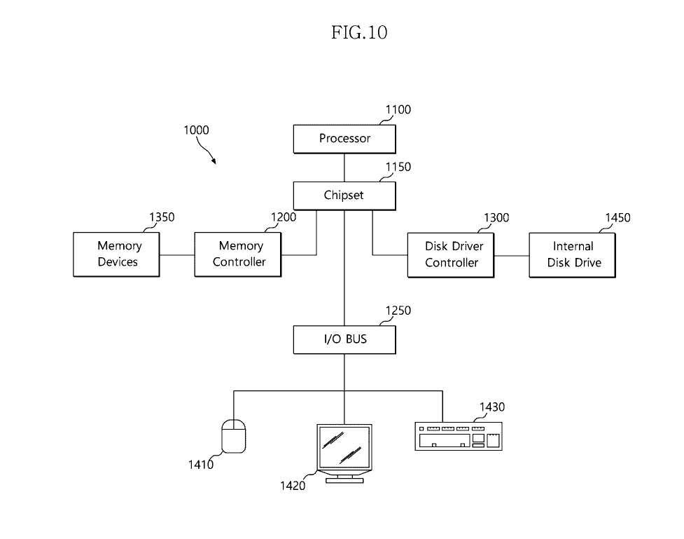

In FIG. 9, a test operation of the memory chip 100-1 including a plurality of channels, for example, the first channel CHANNEL 0 and the second channel CHANNEL 1, according to the all group compress mode will be described.

As the read command RD is inputted, data written in a previous test write process may be simultaneously outputted and compressed in the first to fourth memory banks B0 to B3 by a simultaneous read operation of the first channel CHANNEL 0 and the second channel CHANNEL 1, so that read data Read Data, that is, the compression data groups B0_C<0:7> to B3_C<0:7> may be generated.

The compression data groups B0_C<0:7> to B3_C<0:7> of the first channel CHANNEL 0 and the second channel CHANNEL 1 may be simultaneously latched in respective data processing units 200 according to the strobe signal READ_STRP.

As the group compression enable signal Group_comp_en is activated, the data processing block 200 of the first channel CHANNEL 0 may sequentially output data, which is obtained by compressing again the compression data groups B0_C<0:7> to B3_C<0:7> respectively corresponding to the first to fourth memory banks B0 to B3, according to an order of the first to fourth memory banks B0 to B3 in response to the read start signal READ_START generated in accordance with a read latency RL.

The output of the data obtained by compressing the compression data groups B0_C<0:7> to B3_C<0:7> again may be performed based on the data strobe signal DQS.

The control block 400 of the first channel CHANNEL 0 may generate the read end signal READ_END, which defines data output end, at the time point at which the output of final data, for example, data obtained by compressing B3_C<0:7> is completed.

The second channel CHANNEL 1 sequentially outputs data, which is obtained by compressing again the compression data groups B0_C<0:7> to B3_C<0:7> respectively corresponding to the first to fourth memory banks B0 to B3, according to an order of the first to fourth memory banks B0 to B3 in response to the read end signal READ_END generated in the first channel CHANNEL 0, in substantially the same manner as that of the first channel CHANNEL 0.

The output of the data obtained by compressing the compression data groups B0_C<0:7> to B3_C<0:7> again may be performed based on the data strobe signal DQS.

Referring to FIG. 10, a system 1000 may include one or more processors (i.e., Processor) or, for example but not limited to, central processing units (“CPUs”) 1100. The processor 1100 may be used individually or in combination with other processors. While the processor 1100 will be referred to primarily in the singular, it will be understood to those skilled in the art that a system 1000 with any number of physical or logical processors may be implemented.

A chipset 1150 may be electrically coupled to the processor 1100. The chipset 1150 is a communication pathway for signals between the processor 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

The memory controller 1200 may be electrically coupled to the chipset 1150. The memory controller 1200 can receive a request provided from the processor 1100 through the chipset 1150. The memory controller 1200 may be electrically coupled to one or more memory devices 1350. The memory devices 1350 may include the stack type semiconductor apparatus described above.

The chipset 1150 may also be electrically coupled to the I/O bus 1250. The I/O bus 1250 may serve as a communication pathway for signals from the chipset 1150 to I/O devices 1410, 1420 and 1430. The I/O devices 1410, 1420 and 1430 may include, for example but are not limited to, a mouse 1410, a video display 1420, or a keyboard 1430. The I/O bus 1250 may employ any one of a number of communications protocols to communicate with the I/O devices 1410, 1420 and 1430.

The disk driver controller 1300 may be operably coupled to is the chipset 1150. The disk driver controller 1300 may serve as the communication pathway between the chipset 1150 and one internal disk driver 1450 or more than one internal disk driver 1450. The disk driver controller 1300 and the internal disk driver 1450 may communicate with each other or with the chipset 1150 using virtually any type of communication protocol.

While certain embodiments have been described above, it will be understood to those skilled in the art that the embodiments described are by way of example only. Accordingly, the memory chip and the stack type semiconductor apparatus including the same described herein should not be limited based on the described embodiments. Rather, the memory chip and the stack type semiconductor apparatus including the same described herein should only be limited in light of the claims that follow when taken in conjunction with the above description and accompanying figures.

What is claimed is:

1. A memory chip comprising:
a plurality of memory banks configured to simultaneously output previously stored data according to a read command;
a plurality of data compression blocks configured to generate compression data groups by compressing respective unit data groups outputted from the plurality of memory banks; and
a test control circuit configured to simultaneously latch the compression data groups and sequentially output latched data as test read data according to a read start signal.

2. The memory chip according to claim 1, wherein the test control circuit is configured to sequentially output the latched data according to a repeated order of the plurality of memory banks.

3. The memory chip according to claim 1, wherein the test control circuit comprises:
a data processing block configured to simultaneously latch the compression data groups according to a strobe signal and sequentially output the latched data according to a plurality of output control signals;
a multiplexing block configured to output the test read data by selecting output signals of the data processing block according to a plurality of bank selection signals; and
a control block configured to generate the plurality of output control signals and the plurality of bank selection signals according to the read start signal.

4. The memory chip according to claim 3, wherein the data processing block comprises:
data processing units corresponding to a number of the plurality of memory banks,
wherein the data processing unit comprises:
a plurality of latches configured to simultaneously latch a compression data group corresponding to a corresponding memory bank among the compression data groups according to the strobe signal;
a logic gate configured to output a group compression signal by combining signals latched in the plurality of latches;
a first multiplexer configured to sequentially select and output the signals, which have been latched in the plurality of latches, according to the plurality of output control signals; and
a second multiplexer configured to select and output output of the first multiplexer or the group compression signal outputted from the logic gate according to a group compression enable signal.

5. The memory chip according to claim 3, wherein the control block comprises:
a first counter configured to generate the plurality of bank selection signals according to a clock signal; and
a second counter configured to generate the plurality of output control signals according to a signal of the plurality of bank selection signals.

6. A memory chip comprising:
a plurality of channels including a plurality of memory banks and having a separate input/output interface,
wherein each of the plurality of channels are configured to simultaneously latch compression data groups obtained by compressing respective unit data groups outputted from the plurality of memory banks, sequentially output latched data as test read data according to a read start signal or a read end signal, and generate the read end signal which defines that a final data output has ended.

7. The memory chip according to claim 6, wherein a channel having a highest order of the plurality of channels is configured to perform a data output operation according to the read start signal.

8. The memory chip according to claim 6, wherein remaining channels, except for a channel having a highest order of the plurality of channels, are configured to perform a data output operation according to the read end signal of a previous channel.

9. The memory chip according to claim 6, wherein the plurality of channels are configured to simultaneously output data stored in the plurality of memory banks according to a read command.

10. The memory chip according to claim 6, wherein each of the plurality of channels comprises:
a data processing block configured to simultaneously latch the compression data groups according to a strobe signal and sequentially output latched data according to a plurality of output control signals;
a multiplexing block configured to output the test read data by selecting output signals of the data processing block according to a plurality of bank selection signals; and
a control block configured to generate the plurality of output control signals, the plurality of bank selection signals, and the read end signal according to the read start signal or the read end signal of a previous channel.

11. The memory chip according to claim 10, wherein the data processing block comprises:
data processing units corresponding to a number of the plurality of memory banks,
wherein the data processing unit comprises:
a plurality of latches configured to simultaneously latch a compression data group corresponding to a corresponding memory bank among the compression data groups according to the strobe signal;
a logic gate configured to output a group compression signal by combining signals latched in the plurality of latches;
a first multiplexer configured to sequentially select and output the signals, which have been latched in the plurality of latches, according to the plurality of output control signals; and
a second multiplexer configured to select and output output of the first multiplexer or the group compression signal outputted from the logic gate according to a group compression enable signal.

12. The memory chip according to claim 10, wherein the control block comprises:
a count clock generation unit configured to generate a count clock signal according to the read start signal, the read end signal of the previous channel, and a clock signal;
a first counter configured to generate the plurality of bank selection signals according to the count clock signal; and
a second counter configured to generate the plurality of output control signals according to a signal of the plurality of bank selection signals.

13. A stack type semiconductor apparatus comprising:
a plurality of stacked memory chips in which signal input/output is performed,
wherein each of the plurality of memory chips includes a plurality of channels including a plurality of memory banks, and are configured to simultaneously latch compression data groups obtained by compressing respective unit data groups outputted from the plurality of memory banks of each of the plurality of channels, sequentially output latched data as test read data according to a read start signal or a read end signal of a previous channel, and generate the read end signal which defines that final data output has ended.

14. The stack type semiconductor apparatus according to claim 13, wherein the previous channel includes any one of the plurality of channels in a substantially same memory chip or any one of the plurality of channels of another memory chip.

15. The stack type semiconductor apparatus according to claim 13, wherein a channel having a highest order of the plurality of channels of a highest or lowest memory chip of the plurality of memory chips is configured to perform a data output operation according to the read start signal.

16. The stack type semiconductor apparatus according to claim 13, wherein remaining channels, except for a channel having a highest order of the plurality of channels of a highest or lowest memory chip of the plurality of memory chips, are configured to perform a data output operation according to the read end signal of the previous channel.

17. The stack type semiconductor apparatus according to claim 13, wherein the plurality of memory chips are configured to simultaneously output data stored in the plurality of memory banks according to a read command.

18. The stack type semiconductor apparatus according to claim 13, wherein each of the plurality of channels of the plurality of memory chips comprise:
a data processing block configured to simultaneously latch the compression data groups according to a strobe signal and sequentially output the latched data according to a plurality of output control signals;
a multiplexing block configured to output the test read data by selecting output signals of the data processing block according to a plurality of bank selection signals; and
a control block configured to generate the plurality of output control signals, the plurality of bank selection signals, and the read end signal according to the read start signal or the read end signal of the previous channel.

19. The stack type semiconductor apparatus according to claim 18, wherein the data processing block comprises:
data processing units corresponding to a number of the plurality of memory banks,
wherein the data processing unit comprises:
a plurality of latches configured to simultaneously latch a compression data group corresponding to a corresponding memory bank among the compression data groups according to the strobe signal;
a logic gate configured to output a group compression signal by combining signals latched in the plurality of latches;
a first multiplexer configured to sequentially select and output the signals, which have been latched in the plurality of latches, according to the plurality of output control signals; and
a second multiplexer configured to select and output output of the first multiplexer or the group compression signal outputted from the logic gate according to a group compression enable signal.

20. The stack type semiconductor apparatus according to claim 18, wherein the control block comprises:
a count clock generation unit configured to generate a count clock signal according to the read start signal, the read end signal of the previous channel, and a clock signal;
a first counter configured to generate the plurality of bank selection signals according to the count clock signal; and
a second counter configured to generate the plurality of output control signals according to a signal of the plurality of bank selection signals.

21. The stack type semiconductor apparatus according to claim 13, wherein the test read data is configured to be outputted through through vias.

22. The stack type semiconductor apparatus according to claim 18, wherein the read end signal is configured to be transmitted from any one of the plurality of memory chips to another memory chip through through vias.

23. The memory chip according to claim 1, further comprising:
a test input/output port is configured to allow an external test-related command, test-related data input, and test-related data output.

24. The memory chip according to claim 6, wherein a simultaneous data compression test is possible without separately selecting the plurality of channels.

25. The memory chip according to claim 6, wherein a simultaneous data compression test can be performed without separately selecting the plurality of channels after stacking.

26. The memory chip according to claim 13, wherein a simultaneous data compression test is possible without separately selecting the plurality of channels.

27. The memory chip according to claim 13, wherein a simultaneous data compression test can be performed without separately selecting the plurality of channels after stacking.
